(19) United States
(12) Patent Application Publication
(10) Pub. No.: US 2023/0317556 A1
(43) Pub. Date: Oct. 5, 2023

(54) CHASSIS CUSTOMIZATION WITH HIGH THROUGHPUT ADDITIVE MANUFACTURED MODIFICATION STRUCTURES

(71) Applicant: Intel Corporation, Santa Clara, CA (US)

(72) Inventors: Akhilesh Rallabandi, Chandler, AZ (US); Feras Eid, Chandler, AZ (US)

(73) Assignee: Intel Corporation, Santa Clara, CA (US)

(21) Appl. No.: 17/710,658

(22) Filed: Mar. 31, 2022

(51) Int. Cl. H01L 23/467

(52) U.S. Cl. CPC H01L 23/467

(57) ABSTRACT

A modification structure may be formed within a chassis of an electronic product to improve its thermal dissipation systems, to lessen its weight, and/or to enhance its durability, while maintaining the industrial design/esthetics/ergonomics thereof, wherein the modification structure may comprise a plurality of fused modification material particles. The modification structures may have a higher thermal conductivity than the chassis, may have a lower thermal conductivity than the chassis, may have a lower density than the chassis, and/or may have a higher yield strength than the chassis. In a specific example, the modification structure may extend entirely through the chassis and be sufficiently porous to allow air flow to assist in heat dissipation from the electronic product.

### TECHNICAL FIELD

Embodiments of the present description generally relate to the field of electronic products, and, more specifically, to the formation of modification structures within a chassis or housing of an electronic product that improves the functionality and/or ergonomics of the electronic product.

### BACKGROUND

The integrated circuit industry is continually striving to produce ever faster, smaller, and thinner integrated circuit devices and packages for use in various electronic products, including, but not limited to, computer servers and portable products, such as portable computers, electronic tablets, cellular phones, digital cameras, and the like. The ever smaller and thinner integrated circuit devices and packages, of course, allow for the fabrication of ever smaller and thinner sized electronic products.

As these goals are achieved, the integrated circuit devices become smaller. Accordingly, the density of power consumption of electronic components within the integrated circuit devices has increased, which, in turn, increases the average junction temperature of the integrated circuit device. If the temperature of the integrated circuit device becomes too high, the integrated circuits may be damaged or destroyed. This issue is exacerbated by the chassis or housings, which at least partially encases the integrated circuit device, becoming smaller, as there is less space to incorporate an effective thermal management solution for the integrated circuit devices within the chassis without effecting ergonomics, esthetics, and/or industrial design of the electronic products. Furthermore, smaller chassis or housings also make it more difficult to incorporate features to enhance the durability or decrease the weight of the electronic products without effecting ergonomics, esthetics, and/or industrial design thereof.

Thus, there is an on-going effort to improve the operation, durability, and efficiency of electronic products, while maintaining the industrial design/esthetics/ergonomics thereof.

### BRIEF DESCRIPTION OF THE DRAWINGS

The subject matter of the present disclosure is particularly pointed out and distinctly claimed in the concluding portion of the specification. The foregoing and other features of the present disclosure will become more fully apparent from the following description and appended claims, taken in conjunction with the accompanying drawings. It is understood that the accompanying drawings depict only several embodiments in accordance with the present disclosure and are, therefore, not to be considered limiting of its scope. The disclosure will be described with additional specificity and detail through use of the accompanying drawings, such that the advantages of the present disclosure can be more readily ascertained, in which:

FIG. 1 is a side cross-sectional view of a portion of an electronic system, according to an embodiment of the present description.

FIG. 2 is a side cross-sectional view of a chassis having a recess formed therein, according to an embodiment of the present description.

FIG. 3 is a side cross-sectional view of depositing modification material particles into the recess of FIG. 2, according to an embodiment of the present description.

FIG. 4 is a side cross-sectional view of the inset 4 for FIG. 3, according to one embodiment of the present description.

FIG. 5 is a side cross-sectional view of a modification structure formed in the recess in the chassis of FIG. 2, according to one embodiment of the present description.

FIG. 6 is a flow diagram of a process for forming a modification structure in a chassis, according to an embodiment of the present description.

FIG. 7 is a schematic of an electronic system, according to one embodiment of the present description.

### DETAILED DESCRIPTION

In the following detailed description, reference is made to the accompanying drawings that show, by way of illustration, specific embodiments in which the claimed subject matter may be practiced. These embodiments are described in sufficient detail to enable those skilled in the art to practice the subject matter. It is to be understood that the various embodiments, although different, are not necessarily mutually exclusive. For example, a particular feature, structure, or characteristic described herein, in connection with one embodiment, may be implemented within other embodiments without departing from the spirit and scope of the claimed subject matter. References within this specification to “one embodiment” or “an embodiment” mean that a particular feature, structure, or characteristic described in connection with the embodiment is included in at least one implementation encompassed within the present description. Therefore, the use of the phrase “one embodiment” or “in an embodiment” does not necessarily refer to the same embodiment. In addition, it is to be understood that the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled. In the drawings, like numerals refer to the same or similar elements or functionality throughout the several views, and that elements depicted therein are not necessarily to scale with one another, rather individual elements may be enlarged or reduced in order to more easily comprehend the elements in the context of the present description.

The terms “over”, “to”, “between” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers.

The term “package” generally refers to a self-contained carrier of one or more dice, where the dice are attached to the package substrate, and may be encapsulated for protection, with integrated or wire-bonded interconnects between the dice and leads, pins or bumps located on the external portions of the package substrate. The package may contain a single die, or multiple dice, providing a specific function. The package is usually mounted on a printed circuit board for interconnection with other packaged integrated circuits and discrete components, forming a larger circuit.

Here, the term “cored” generally refers to a substrate of an integrated circuit package built upon a board, card or wafer comprising a non-flexible stiff material. Typically, a small printed circuit board is used as a core, upon which integrated circuit device and discrete passive components may be soldered. Typically, the core has vias extending from one side to the other, allowing circuitry on one side of the core to be coupled directly to circuitry on the opposite side of the core. The core may also serve as a platform for building up layers of conductors and dielectric materials.

Here, the term “coreless” generally refers to a substrate of an integrated circuit package having no core. The lack of a core allows for higher-density package architectures, as the through-vias have relatively large dimensions and pitch compared to high-density interconnects.

Here, the term “land side”, if used herein, generally refers to the side of the substrate of the integrated circuit package closest to the plane of attachment to a printed circuit board, motherboard, or other package. This is in contrast to the term “die side”, which is the side of the substrate of the integrated circuit package to which the die or dice are attached.

Here, the term “dielectric” generally refers to any number of non-electrically conductive materials that make up the structure of a package substrate. For purposes of this disclosure, dielectric material may be incorporated into an integrated circuit package as layers of laminate film or as a resin molded over integrated circuit dice mounted on the substrate.

Here, the term “metallization” generally refers to metal layers formed over and through the dielectric material of the package substrate. The metal layers are generally patterned to form metal structures such as traces and bond pads. The metallization of a package substrate may be confined to a single layer or in multiple layers separated by layers of dielectric.

Here, the term “bond pad” generally refers to metallization structures that terminate integrated traces and vias in integrated circuit packages and dies. The term “solder pad” may be occasionally substituted for “bond pad” and carries the same meaning.

Here, the term “solder bump” generally refers to a solder layer formed on a bond pad. The solder layer typically has a round shape, hence the term “solder bump”.

Here, the term “substrate” generally refers to a planar platform comprising dielectric and metallization structures. The substrate mechanically supports and electrically couples one or more IC dies on a single platform, with encapsulation of the one or more IC dies by a moldable dielectric material. The substrate generally comprises solder bumps as bonding interconnects on both sides. One side of the substrate, generally referred to as the “die side”, comprises solder bumps for chip or die bonding. The opposite side of the substrate, generally referred to as the “land side”, comprises solder bumps for bonding the package to a printed circuit board.

Here, the term “assembly” generally refers to a grouping of parts into a single functional unit. The parts may be separate and are mechanically assembled into a functional unit, where the parts may be removable. In another instance, the parts may be permanently bonded together. In some instances, the parts are integrated together.

Throughout the specification, and in the claims, the term “connected” means a direct connection, such as electrical, mechanical, or magnetic connection between the things that are connected, without any intermediary devices.

The term “coupled” means a direct or indirect connection, such as a direct electrical, mechanical, magnetic or fluidic connection between the things that are connected or an indirect connection, through one or more passive or active intermediary devices.

The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The vertical orientation is in the z-direction and it is understood that recitations of “top”, “bottom”, “above” and “below” refer to relative positions in the z-dimension with the usual meaning. However, it is understood that embodiments are not necessarily limited to the orientations or configurations illustrated in the figure.

The terms “substantially,” “close,” “approximately,” “near,” and “about,” generally refer to being within +/−10% of a target value (unless specifically specified). Unless otherwise specified the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

Views labeled “cross-sectional”, “profile” and “plan” correspond to orthogonal planes within a cartesian coordinate system. Thus, cross-sectional and profile views are taken in the x-z plane, and plan views are taken in the x-y plane. Typically, profile views in the x-z plane are cross-sectional views. Where appropriate, drawings are labeled with axes to indicate the orientation of the figure.

Embodiments of the present description relate to forming modification structures within a chassis of an electronic product to improve its thermal dissipation systems, to lessen its weight, and/or to enhance its durability, while maintaining the industrial design, esthetics, and/or ergonomics thereof. In the various embodiments of the present description, the modification structures within the chassis may comprise a plurality of fused modification material particles. In one embodiment of the present description, the modification structures may extend entirely through the chassis and be sufficiently porous to allow air flow, which in conjunction with a fan may assist in heat dissipation from the electronic product. In another embodiment of the present description, the modification structures may be formed from highly, thermally conductive modification material particles to assist in heat dissipation from the electronic product. In still another embodiment of the present description, the modification structures may be formed from highly, thermally insulative modification material particles to prevent or redirect heat dissipation from specific areas of the electronic product. In yet still another embodiment of the present description, the modification structures may be formed from relatively low weight modification material particles to reduce the weight of the electronic product. In a further embodiment of the present description, the modification structures may be formed from relatively high stiffness or yield strength modification material particles in areas of high mechanical stresses and cycling in the chassis.

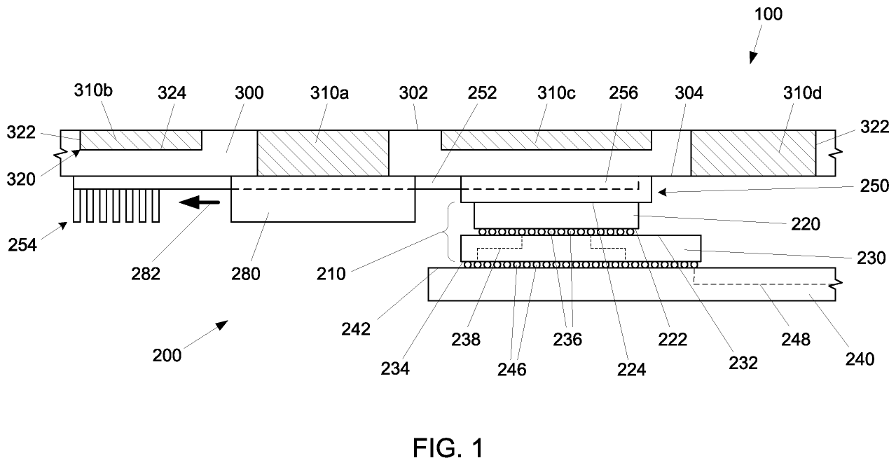

FIG. 1 illustrates a portion of an electronic system 100, according to an embodiment of the present description. As illustrated, the electronic system 100 may include the integrated circuit assembly 200, wherein the integrated circuit assembly 200 may comprise an integrated circuit package 210 having at least one integrated circuit device 220 electrically attached to an electronic substrate 230 in a configuration generally known as a flip-chip or controlled collapse chip connection (“C4”) configuration, according to an embodiment of the present description. The electronic substrate 230 may be any appropriate structure, including, but not limited to, an interposer. The electronic substrate 230 may have a first surface 232 and an opposing second surface 234. The electronic substrate 230 may comprise a plurality of dielectric material layers (not shown), which may include build-up films and/or solder resist layers, and may be composed of an appropriate dielectric material, including, but not limited to, bismaleimide triazine resin, fire retardant grade 4 material, polyimide material, silica filled epoxy material, glass reinforced epoxy material, and the like, as well as low-k and ultra low-k dielectrics (dielectric constants less than about 3.6), including, but not limited to, carbon doped dielectrics, fluorine doped dielectrics, porous dielectrics, organic polymeric dielectrics, and the like.

The electronic substrate 230 may further include conductive routes 238 (shown in dashed lines) extending through the electronic substrate 230. As will be understood to those skilled in the art, the conductive routes 238 may be a combination of conductive traces (not shown) and conductive vias (not shown) extending through the plurality of dielectric material layers (not shown). These conductive traces and conductive vias are well known in the art and are not shown in FIG. 1 for purposes of clarity and conciseness. The conductive traces and the conductive vias may be made of any appropriate conductive material, including but not limited to, metals, such as copper, silver, nickel, gold, and aluminum, alloys thereof, and the like. As will be understood to those skilled in the art, the electronic substrate 230 may be a cored substrate or a coreless substrate. In one embodiment of the present description, the electronic substrate 230 may comprise a silicon or glass interposer. In another embodiment of the present description, the electronic substrate 230 may include active and/or passive devices.

The integrated circuit device 220 may be any appropriate device, including, but not limited to, a microprocessor, a chipset, a graphics device, a wireless device, a memory device, an application specific integrated circuit, combinations thereof, stacks thereof, or the like. As shown, the integrated circuit device 220 may have a frontside surface 222 and an opposing backside surface 224.

In an embodiment of the present description, the integrated circuit device 220 may be electrically attached to the electronic substrate 230 with a plurality of device-to-substrate interconnects 236. In one embodiment of the present description, the device-to-substrate interconnects 236 may extend between bond pads (not shown) on the first surface 232 of the electronic substrate 230 and bond pads (not shown) on the frontside surface 222 of the integrated circuit device 220. The device-to-substrate interconnects 236 may be any appropriate electrically conductive material or structure, including, but not limited to, solder balls, metal bumps or pillars, metal filled epoxies, or a combination thereof. In one embodiment, the device-to-substrate interconnects 236 may be solder balls formed from tin, lead/tin alloys (for example, 63% tin/37% lead solder), and high tin content alloys (e.g., 90% or more tin—such as tin/bismuth, eutectic tin/silver, ternary tin/silver/copper, eutectic tin/copper, and similar alloys). In another embodiment, the device-to-substrate interconnects 236 may be copper bumps or pillars. In a further embodiment, the device-to-substrate interconnects 236 may be metal bumps or pillars coated with a solder material. In still a further embodiment, the device-to-substrate interconnects 236 may be anisotropic conductive film.

The bond pads (not shown) on the frontside surface 222 may be in electrical communication with integrated circuitry (not shown) within the integrated circuit device 220. The bond pads (not shown) on the first surface 232 of the electronic substrate 230 may be in electrical contact with the conductive routes 238. The conductive routes 238 may extend through the electronic substrate 230 and be connected to bond pads (not shown) on the second surface 234 of the electronic substrate 230. As will be understood to those skilled in the art, the electronic substrate 230 may reroute a fine pitch (center-to-center distance between the bond pads) of the integrated circuit device bond pads (not shown) to a relatively wider pitch of the bond pads (not shown) on the second surface 234 of the electronic substrate 230.

As further shown in FIG. 1, the electronic substrate 230 of the integrated circuit package 210 may be attached to a board substrate 240, such as a motherboard, with a plurality of substrate-to-board interconnects 246, in a configuration generally known as a flip-chip or controlled collapse chip connection (“C4”) configuration. The board substrate 240 may comprise a plurality of dielectric material layers and metallization 248 as described with regard to the electronic substrate 230.

In one embodiment of the present description, the substrate-to-board interconnects 246 may extend between bond pads (not shown) proximate a first surface 242 of the board substrate 240 and bond pads (not shown) proximate the second surface 234 of the electronic substrate 230. Although FIG. 1 shows the integrated circuit package 210 attached to the board substrate 240 with an interconnect-type attachment, the embodiments of the present description are not so limited. For example, the integrated circuit package 210 may be attached to a socket (not shown) that is electrically attached to the first surface 242 of the board substrate 240.

In a further embodiment of the present description, as shown in FIG. 1, the integrated circuit assembly 200 may include a heat dissipation device 250. The heat dissipation device 250 may be any appropriate assembly known in the art. In one embodiment, the heat dissipation device 250 may include at least one heat pipe 252, wherein the at least one heat pipe 252 may convey heat away from the integrated circuit device 220 to an external heat sink 254 (illustrated as a plurality of fin structures). As will be understood to those skilled in the art, the heat pipe(s) 252 operate with a working fluid (not illustrated), wherein the working fluid transfers heat by vaporizing near the integrated circuit device 220, condensing near the external heat sink 254, and returning from the external heat sink 254 through a wicking material (not shown). The structures and mechanisms of heat pipes are well known in the art and for the purposes of clarity and conciseness will not be described in detail.

The heat dissipation device 250 may further include a base plate 256 that may be attached to the at least one heat pipe 252. The base plate 256 may be thermally attached to the at least one integrated circuit device 220 with a thermal interface material (not shown) disposed therebetween. The thermal interface material may include thermal greases, gap pads, polymers, and the like. The base plate 256 is typically made of a high thermal conductivity material, such as copper. As will be understood, the base plate 256 may improve structural rigidity of the heat dissipation device 250 and may assist in spreading heat laterally beyond the footprint of the at least one integrated circuit device 220 to increase the effective area of the hot interface of the at least one heat pipe 252.

As further shown in FIG. 1, the electronic system 100 may also include a chassis 300 that at least partially encases or at least partially houses the integrated circuit assembly 200 (the chassis 300 shown only in part in FIG. 1). The chassis 300 may have a first surface 302 and an opposing second surface 304. In one embodiment, the integrated circuit assembly 200 may be adjacent the second surface 304 of the chassis 300. In a further embodiment of the present description, the heat dissipation device 250 may abut the second surface 304 of the chassis 300.

As shown in FIG. 1, the chassis 300 may have at least one modification structure formed therein for improving the performance of the integrated circuit assembly 200 and/or of the chassis 300. It is noted that the modification structures are labeled as elements 310a, 310b, 310c, and 310d in FIG. 1, and may be referred to collectively as modification structure(s) 310 in subsequent figures. In one embodiment of the present description, the modification structure (shown as elements 310b and 310c) may extend partially through the chassis 300 from either the first surface 302 or the second surface 304 of the chassis 300. In another embodiment of the present description, the modification structure (shown as elements 310a and 310d) may extend entirely through the chassis 300, i.e., from the first surface 302 to the second surface 304 of the chassis 300.

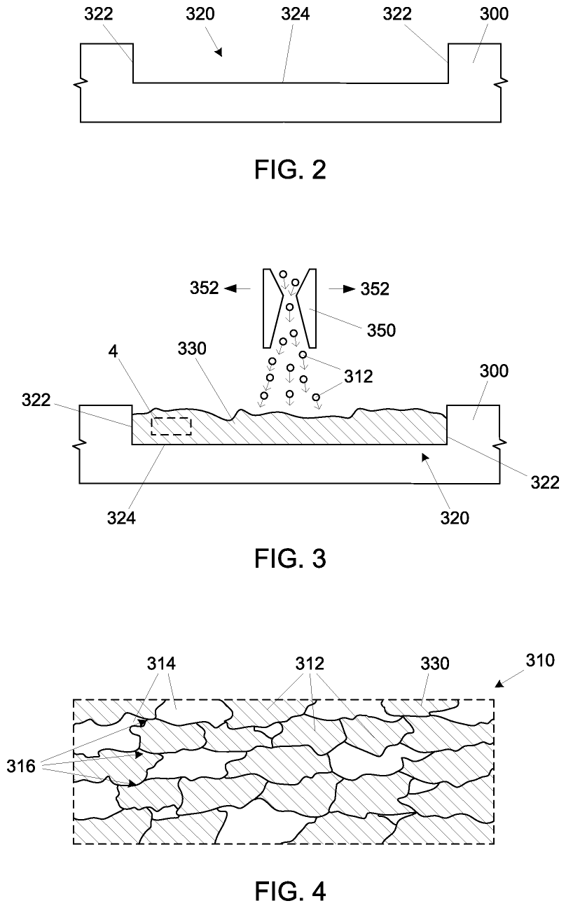

In the various embodiments of the present description, the modification structure within the chassis 300 may be formed by an additive process, such as high throughput additive manufacturing (“HTAM”). As shown in FIG. 2, a recess 320 may be formed to extend into the chassis 300. In one embodiment of the present description, the recess 320 may be defined by at least one sidewall 322 and a bottom surface 324. The recess 320 may be formed during the formation of the chassis 300 by any appropriate process known in the art, including, but not limited to, stamping, molding, or the like. Additionally, the recess 320 may be formed after the formation of the chassis 300 by any appropriate process known in the art, including, but not limited to, skiving, laser ablation, ion bombardment, and the like. It is noted, that if the recess 320 extends entirely through the chassis 300, i.e., from the first surface 302 to the second surface 304 thereof, it would be defined only by the sidewall(s) 322 (see FIG. 1).

In one embodiment of the present description, the modification structures 310a, 310b, 310c, 310d (see FIG. 1) may be formed with a “coldspray” HTAM process. As the coldspray process is known in the art, it will be only concisely discussed herein. With a coldspray process, particles of a desired material, e.g., modification material particles 312, are accelerated in a carrier jet (e.g., compressed air or nitrogen) by passing the jet through a converging diverging nozzle 350. The jet exits the nozzle 350 at a high velocity and reaches an underlying substrate, such as the bottom surface 324 of the recess 320 of the chassis 300, where the impact causes the modification material particles 312 in the jet to plastically deform and bond or fuse to the bottom surface 324 of the recess 320. Subsequent layers of the modification material particles 312 similarly adhere or fuse to each underlying layer upon continued jet impact, producing fast buildup (e.g., layers that are a few hundred microns thick can be deposited over an area of about 100-1000 mm² in a few seconds) to form a matrix structure 330, as will be discussed. The nozzle 350 may be moved (shown as arrows 352) in a specific pattern across the chassis 300 during the spray process. Moreover, unlike thermal spraying techniques, this approach does not require melting the modification material particles 312, thus protecting both the modification material particles 312 and the chassis 300 from experiencing excessive processing temperatures. Because additive manufacturing, such as coldspray, is used, it eliminates the need for using lithography and the many steps associated with it (resist deposition, exposure, resist development, and resist removal) that are characteristic of subtractive or semi-additive methods, such as plating, sputtering, and the like. Additionally, 3D topography can be easily created, if needed, as will be understood to those skilled in the art. It is noted that stencils or masks can be used to specifically pattern the deposition of the modification material particles 312, as will also be understood to those skilled in the art. It is further noted that the modification material particles 312 may be a mixture of differing material particles.

FIG. 4 further illustrates deposition of the modification material particles 312 to form the matrix structure 330, in accordance with some embodiments of the HTAM process, as previously discussed. As shown, the microstructure of the matrix structure 330 comprises deformed modification material particles 312 fused to one another and layered in a lamellar structure/manner and voids 314 (inherently formed during the deposition process). At sufficient magnification, fusion boundaries 316 between the modification material particles 312 are apparent (e.g., the surfaces where the modification material particles 312 fuse together), as distinguished from atomic deposition processes, such as plating. The lamellar structure of the modification material particles 312 may be evident within the matrix structure 330, which is indicative of the impact between the modification material particles 312 and the bottom surface 324 of the recess 320 of the chassis 300 (see FIG. 3) and between the modification material particles 312 and the previous deposited modification material particles 312, where most of the modification material particles 312 plastically deform and flatten. It is noted, that if the recess 320 extends entirely through the chassis 300, i.e., from the first surface 302 to the second surface 304 thereof, it would be defined only by the sidewalls 322, and may be placed on a carrier (not shown) to act as the bottom surface 324 of the recess 320 during the formation of the matrix structure 330.

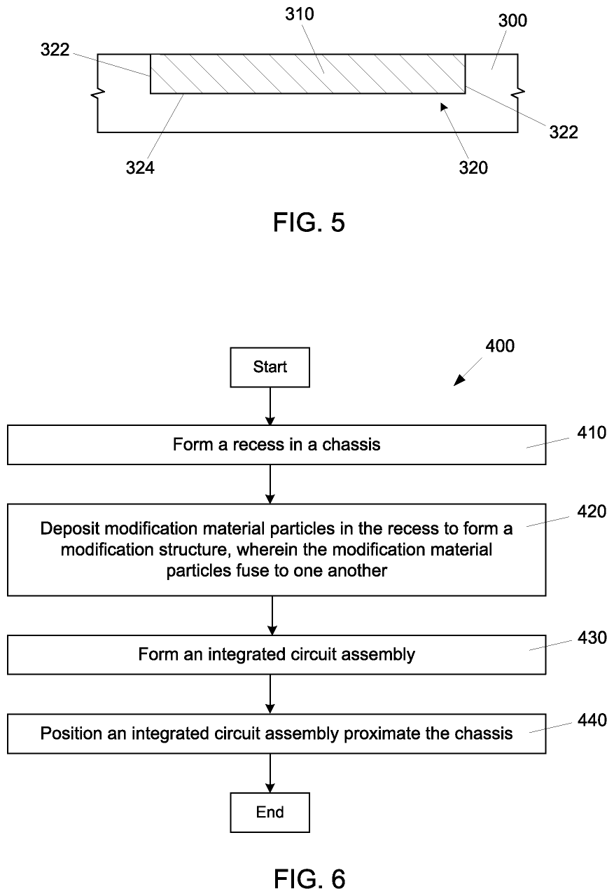

As shown in FIG. 5, the deposited modification material particles 312 (see FIG. 4) may be planarized, such as by chemical mechanical polishing, to form the modification structure 310.

Referring back to FIG. 1, in one embodiment of the present description, the at least one modification structure 310a may extend entirely through the chassis and be sufficiently porous to allow air flow. The electronic system 100 may include a fan 280 positioned proximate the at least one modification structure 310a to draw air therethrough and toward (arrow 282) the external heat sink 254 to assist in heat dissipation from the integrated circuit device 220. The at least one modification structure 310a may thus function as a “hidden vent” to enable airflow without disrupting the esthetics or “industrial design” (ID) of the chassis 300, as it will look similar to the rest of the chassis 300 with the same functionality as that of known fan vents. In another embodiment of the present description, the modification structure 310a may include, but is not limited to, copper, aluminum, nickel, carbon (such as diamond and graphite), silicon carbide, aluminum nitride, combinations thereof, combinations with other materials, and the like. In one embodiment of the present description, the modification structure 310a may include a plastic material, including, but not limited to, polyethylene terephthalate, polytetrafluoroethylene, and the like.

In another embodiment of the present description, the modification structures, such as element 310b may be formed from highly, thermally conductive modification material particles to assist in heat dissipation from the electronic product. In one embodiment of the present description, the modification structure 310b may have a thermal conductivity that is greater than a thermal conductivity of the chassis 300. In an embodiment of the present description, the modification structure 310b may be positioned proximate the heat dissipation device 250 (shown as being adjacent the external heat sink 254). In another embodiment of the present description, the modification structure 310b may include, but is not limited to, copper, aluminum, nickel, carbon (such as diamond and graphite), silicon carbide, aluminum nitride, combinations thereof, combinations with other materials, and the like.

In still another embodiment of the present description, the modification structure 310c may be formed from highly, thermally insulative modification material particles to prevent or redirect heat dissipation from the chassis 330. This will allow for the thermal decoupling of the heat sources, such as the integrated circuit device 220 from the areas of ergonomic concern, without adding significant overhead to the fabrication of the chassis 300 or compromising the aesthetics of the chassis 300. In one embodiment of the present description, since air is a poor conductor of heat, a modification structure 310c may be highly porous. In another embodiment of the present description, the modification structure 310c may be a low-thermal conductive material, such as plastic material(s), including, but not limited to, polyethylene terephthalate, polytetrafluoroethylene, and the like. Thus, in one embodiment, the modification structure 310c may have a lower thermal conductivity than a thermal conductivity of the chassis 300.

In yet still another embodiment of the present description, the modification structures 310d may be formed from relatively low weight material to reduce the weight of the chassis 300. In one embodiment of the present description, the modification structure 310d may have a density that is lower than a density of the chassis 300. This may be achieved through forming the modification structure 310d with a material that has a lower density than a density of the chassis 300, with a material that is more porous than the material of the chassis 300, or both.

In a further embodiment of the present description, the modification structures 310a, 310b, 310c, and/or 310d may be formed from relatively high stiffness or yield strength material in areas of high mechanical stresses and cycling in the chassis 300. In one embodiment of the present description, a yield strength of the modification structure(s) 310a, 310b, 310c, and/or 310d may be greater than a yield strength of the chassis 300.

FIG. 4 is a flow chart of a process 400 of fabricating a modification structure. As set forth in block 410, a recess in a chassis may be formed. Modification material particles may be deposited in the recess of the chassis to form a modification structure, wherein the modification material particles fuse to one another, as set forth in block 420. As set forth in block 430, forming an integrated circuit assembly. The integrated circuit assembly may be positioned proximate the chassis, as set forth in block 440.

FIG. 5 illustrates an electronic or computing device/system 500 in accordance with one implementation of the present description. The computing device 500 may include a housing or chassis 501 having a board 502 disposed therein. The computing device 500 may include a number of integrated circuit components, including but not limited to a processor 504, at least one communication chip 506A, 506B, volatile memory 508 (e.g., DRAM), non-volatile memory 510 (e.g., ROM), flash memory 512, a graphics processor or CPU 514, a digital signal processor (not shown), a crypto processor (not shown), a chipset 516, an antenna, a display (touchscreen display), a touchscreen controller, a battery, an audio codec (not shown), a video codec (not shown), a power amplifier (AMP), a global positioning system (GPS) device, a compass, an accelerometer (not shown), a gyroscope (not shown), a speaker, a camera, and a mass storage device (not shown) (such as hard disk drive, compact disk (CD), digital versatile disk (DVD), and so forth). Any of the integrated circuit components may be physically and electrically coupled to the board 502. In some implementations, at least one of the integrated circuit components may be a part of the processor 504.

The communication chip enables wireless communications for the transfer of data to and from the computing device. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device may include a plurality of communication chips. For instance, a first communication chip may be dedicated to shorter range wireless communications such as Wi-Fi and Bluetooth and a second communication chip may be dedicated to longer range wireless communications such as GPS, EDGE, GPRS, CDMA, WiMAX, LTE, Ev-DO, and others.

The term “processor” may refer to any device or portion of a device that processes electronic data from registers and/or memory to transform that electronic data into other electronic data that may be stored in registers and/or memory.

In one embodiment, the computing device 500 may include a housing or chassis 501 that includes at least one modification structure therein to improve the thermal dissipation systems of the computing device 500, to lessen the weight of the computing device 500, and/or enhance the durability of the computing device 500, while maintaining the industrial design/esthetics/ergonomics thereof, wherein the modification structure may comprise a plurality of fused modification material particles.

In various implementations, the computing device may be a laptop, a netbook, a notebook, an ultrabook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, or a digital video recorder. In further implementations, the computing device may be any other electronic device that processes data.

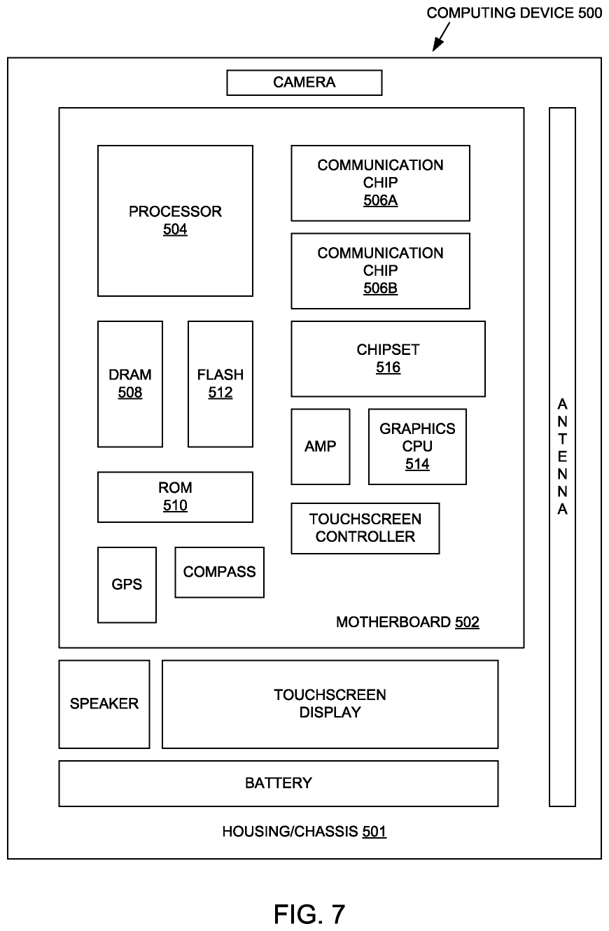

It is understood that the subject matter of the present description is not necessarily limited to specific applications illustrated in FIGS. 1-7. The subject matter may be applied to other integrated circuit devices and assembly applications, as well as any appropriate electronic application, as will be understood to those skilled in the art.

The following examples pertain to further embodiments and specifics in the examples may be used anywhere in one or more embodiments, wherein Example 1 is an apparatus, comprising a chassis, wherein the chassis includes at least one recess and a modification structure disposed within the at least one recess, wherein the modification structure comprises a plurality of fused modification material particles.

In Example 2, the subject matter of Example 1 can optionally include the modification structure having a higher thermal conductivity than a thermal conductivity of the chassis.

In Example 3, the subject matter of Example 1 can optionally include the modification structure having a lower thermal conductivity than a thermal conductivity of the chassis.

In Example 4, the subject matter of any of Examples 1 to 3 can optionally include the modification structure having a lower density than a density of the chassis.

In Example 5, the subject matter of any of Examples 1 to 4 can optionally include the modification structure having a higher yield strength than a yield strength of the chassis.

In Example 6, the subject matter of any of Examples 1 to 5 can optionally include the chassis including a first surface and an opposing second surface, and wherein the at least one recess extends into the chassis from one of the first surface and the second surface of the chassis.

In Example 7, the subject matter of any of Examples 1 to 5 can optionally include the chassis including a first surface and an opposing second surface, and wherein the at least one recess extends through the chassis from the first surface and the second surface of the chassis.

In Example 8, the subject matter of Example 7 can optionally include the modification structure being sufficiently porous to allow air flow therethrough.

In Example 9, the subject matter of Example 8 can optionally include a fan adjacent the modification structure.

Example 10 is an apparatus, comprising an integrated circuit assembly; and a chassis at least partially encasing the integrated circuit assembly, wherein the chassis includes at least one recess; and a modification structure disposed within the at least one recess, wherein the modification structure comprises a plurality of fused modification material particles.

In Example 11, the subject matter of Example 10 can optionally include the modification structure having a higher thermal conductivity than a thermal conductivity of the chassis.

In Example 12, the subject matter of Example 10 can optionally include the modification structure having a lower thermal conductivity than a thermal conductivity of the chassis.

In Example 13, the subject matter of any of Examples 10 to 12 can optionally include the modification structure having a lower density than a density of the chassis.

In Example 14, the subject matter of any of Examples 10 to 13 can optionally include the modification structure having a higher yield strength than a yield strength of the chassis.

In Example 15, the subject matter of any of Examples 10 to 14 can optionally include the chassis including a first surface and an opposing second surface, and wherein the at least one recess extends into the chassis from one of the first surface and the second surface of the chassis.

In Example 16, the subject matter of any of Examples 10 to 14 can optionally include the chassis including a first surface and an opposing second surface, and wherein the at least one recess extends through the chassis from the first surface and the second surface of the chassis.

In Example 17, the subject matter of Example 16 can optionally include the modification structure being sufficiently porous to allow air flow therethrough.

In Example 18, the subject matter of Example 17 can optionally include a fan adjacent the modification structure.

Example 19 is a system, comprising a board substrate; an integrated circuit assembly electrically attached to the board substrate; and a chassis at least partially encasing the integrated circuit assembly, wherein the chassis includes at least one recess; and a modification structure disposed within the at least one recess, wherein the modification structure comprises a plurality of fused modification material particles.

In Example 20, the subject matter of Example 19 can optionally include the modification structure having a higher thermal conductivity than a thermal conductivity of the chassis.

In Example 21, the subject matter of Example 19 can optionally include the modification structure having a lower thermal conductivity than a thermal conductivity of the chassis.

In Example 22, the subject matter of any of Examples 19 to 21 can optionally include the modification structure having a lower density than a density of the chassis.

In Example 23, the subject matter of any of Examples 19 to 22 can optionally include the modification structure having a higher yield strength than a yield strength of the chassis.

In Example 24, the subject matter of any of Examples 19 to 23 can optionally include the chassis including a first surface and an opposing second surface, and wherein the at least one recess extends into the chassis from one of the first surface and the second surface of the chassis.

In Example 25, the subject matter of any of Examples 19 to 23 can optionally include the chassis including a first surface and an opposing second surface, and wherein the at least one recess extends through the chassis from the first surface and the second surface of the chassis.

In Example 26, the subject matter of Example 25 can optionally include the modification structure being sufficiently porous to allow air flow therethrough.

In Example 27, the subject matter of Example 26 can optionally include a fan adjacent the modification structure.

Having thus described in detail embodiments of the present invention, it is understood that the invention defined by the appended claims is not to be limited by particular details set forth in the above description, as many apparent variations thereof are possible without departing from the spirit or scope thereof.

What is claimed is:

1. An apparatus, comprising:
a chassis, wherein the chassis includes:
at least one recess; and
a modification structure disposed within the at least one recess, wherein the modification structure comprises a plurality of fused modification material particles.

2. The apparatus of claim 1, wherein the modification structure has a higher thermal conductivity than a thermal conductivity of the chassis.

3. The apparatus of claim 1, wherein the modification structure has a lower thermal conductivity than a thermal conductivity of the chassis.

4. The apparatus of claim 1, wherein the modification structure has a lower density than a density of the chassis.

5. The apparatus of claim 1, wherein the modification structure has a higher yield strength than a yield strength of the chassis.

6. The apparatus of claim 1, wherein the chassis includes a first surface and an opposing second surface, and wherein the at least one recess extends into the chassis from one of the first surface and the second surface of the chassis.

7. The apparatus of claim 1, wherein the chassis includes a first surface and an opposing second surface, and wherein the at least one recess extends through the chassis from the first surface to the second surface thereof.

8. The apparatus of claim 7, wherein the modification structure is sufficiently porous to allow air flow therethrough.

9. An apparatus, comprising:
an integrated circuit assembly;
a chassis at least partially encasing the integrated circuit assembly, wherein the chassis includes:
at least one recess; and
a modification structure disposed within the at least one recess, wherein the modification structure comprises a plurality of fused modification material particles.

10. The apparatus of claim 9, wherein the modification structure has a higher thermal conductivity than a thermal conductivity of the chassis.

11. The apparatus of claim 9, wherein the modification structure has a lower thermal conductivity than a thermal conductivity of the chassis.

12. The apparatus of claim 9, wherein the modification structure has a lower density than a density of the chassis.

13. The apparatus of claim 9, wherein the modification structure has a higher yield strength than a yield strength of the chassis.

14. The apparatus of claim 9, wherein the chassis includes a first surface and an opposing second surface, and wherein the at least one recess extends into the chassis from one of the first surface and the second surface of the chassis.

15. The apparatus of claim 9, wherein the chassis includes a first surface and an opposing second surface, and wherein the at least one recess extends through the chassis from the first surface to the second surface thereof.

16. The apparatus of claim 15, wherein the modification structure is sufficiently porous to allow air flow therethrough.

17. The apparatus of claim 16, further comprising a fan adjacent the modification structure.

18. A system, comprising:
a board substrate;
an integrated circuit assembly electrically attached to the board substrate; and
a chassis at least partially encasing the integrated circuit assembly, wherein the chassis includes:
at least one recess; and
a modification structure disposed within the at least one recess, wherein the modification structure comprises a plurality of fused modification material particles.

19. The system of claim 18, wherein the modification structure has a higher thermal conductivity than a thermal conductivity of the chassis.

20. The system of claim 18, wherein the modification structure has a lower thermal conductivity than a thermal conductivity of the chassis.

21. The system of claim 18, wherein the modification structure has a lower density than a density of the chassis.

22. The system of claim 18, wherein the modification structure has a higher yield strength than a yield strength of the chassis.

23. The system of claim 18, wherein the chassis includes a first surface and an opposing second surface, and wherein the at least one recess extends into the chassis from one of the first surface and the second surface of the chassis.

24. The system of claim 18, wherein the chassis includes a first surface and an opposing second surface, and wherein the at least one recess extends through the chassis from the first surface to the second surface thereof.

25. The system of claim 24, wherein the modification structure is sufficiently porous to allow air flow therethrough.
